(19) United States
(12) Patent Application Publication
(10) Pub. No.: US 2024/0321884 A1
(43) Pub. Date: Sep. 26, 2024

(54) SEMICONDUCTOR DEVICE AND METHOD OF FABRICATING THE SAME

(71) Applicant: Samsung Electronics Co., Ltd., Suwon-si (KR)

(72) Inventors: Inhyun SONG, Suwon-si (KR); Junggil YANG, Suwon-si (KR); Sangmoon LEE, Suwon-si (KR); Myunggil KANG, Suwon-si (KR); Jongsu KIM, Suwon-si (KR); Beomjin PARK, Suwon-si (KR)

(73) Assignee: Samsung Electronics Co., Ltd., Suwon-si (KR)

(21) Appl. No.: 18/442,590

(22) Filed: Feb. 15, 2024

(30) Foreign Application Priority Data
Mar. 24, 2023 (KR) 10-2023-0039147
May 19, 2023 (KR) 10-2023-0064984

(51) Int. Cl. H01L 27/092; H01L 21/8238; H01L 29/06; H01L 29/423; H01L 29/49; H01L 29/66; H01L 29/775; H01L 29/786

(52) U.S. Cl. CPC H01L 27/092; H01L 21/823807; H01L 21/823842; H01L 29/0673; H01L 29/42392; H01L 29/4908; H01L 29/66439; H01L 29/775; H01L 29/78696

(57) ABSTRACT

Provided is a semiconductor device including a substrate, a fin-type active region protruding on the substrate, a channel region on the fin-type active region and including a plurality of active patterns extending in a first horizontal direction and a semiconductor material layer, a gate line extending in a second horizontal direction that is perpendicular to the first horizontal direction and covering the channel region on the fin-type active region, and a pair of source/drain regions at both sides of the gate line on the fin-type active region, wherein a work function of the semiconductor material layer is different from a work function of the plurality of active patterns, the semiconductor material layer surrounds portions of the gate line between the plurality of active patterns, and the gate line is separated from the pair of source/drain regions with the semiconductor material layer therebetween.

### CROSS-REFERENCE TO RELATED APPLICATION

This application is based on and claims priority under 35 U.S.C. § 119 to Korean Patent Application Nos. 10-2023-0039147, filed on Mar. 24, 2023, and 10-2023-0064984, filed on May 19, 2023, in the Korean Intellectual Property Office, the disclosures of each of which are incorporated by reference herein in their entireties.

### BACKGROUND

The inventive concepts relate to semiconductor devices and methods of fabricating the same, and more particularly, to semiconductor devices including transistors with different threshold voltages and methods of fabricating the same.

As one of the scaling techniques to increase the density of an integrated circuit device, a multi-gate transistor having a fin-shaped or nanowire (or nanosheet)-shaped silicon body formed on a substrate and having a gate formed on the surface of the silicon body has been proposed. Because such a multi-gate transistor uses a three-dimensional channel, it is easy to scale the multi-gate transistor. In addition, the current control capability of the multi-gate transistor may be improved even without increasing the gate length of the multi-gate transistor. Also, a short channel effect (SCE) that the potential of a channel region is affected by a drain voltage may be effectively suppressed.

### SUMMARY

The inventive concepts provide semiconductor devices including transistors with different threshold voltages and methods of fabricating the same.

The inventive concepts also provide semiconductor devices of which a process is simplified and methods of fabricating the same.

The problems to be solved by the technical ideas of the inventive concepts are not limited to the problems mentioned above, and the other problems could be clearly understood by those of ordinary skill in the art from the description below.

According to some aspects of the inventive concepts, there is provided a semiconductor device including a substrate, a fin-type active region protruding on the substrate, a channel region on the fin-type active region and including a plurality of active patterns extending in a first horizontal direction and a semiconductor material layer, a gate line extending in a second horizontal direction, the second horizontal direction being perpendicular to the first horizontal direction, the gate line covering the channel region on the fin-type active region, and a pair of source/drain regions at both sides of the gate line on the fin-type active region, wherein a work function of the semiconductor material layer is different from a work function of the plurality of active patterns, the semiconductor material layer surrounds portions of the gate line between the plurality of active patterns, and the gate line is separated from the pair of source/drain regions with the semiconductor material layer therebetween.

According to some aspects of the inventive concepts, there is provided a semiconductor device including a substrate including a first area and a second area, first and second fin-type active regions protruding on the substrate, a first channel region on the first fin-type active region and including a plurality of first active patterns extending in a first horizontal direction and a semiconductor material layer surrounding at least portions of the plurality of first active patterns, a first gate line covering the first channel region on the first fin-type active region, a second channel region on the second fin-type active region and including a plurality of second active patterns extending in the first horizontal direction, a second gate line covering the second channel region on the second fin-type active region, a pair of first source/drain regions at both sides of the first gate line on the first fin-type active region, and a pair of second source/drain regions at both sides of the second gate line on the second fin-type active region, wherein the first fin-type active region is in the first area of the substrate, the second fin-type active region is in the second area of the substrate, and in the semiconductor material layer, at least one of a surface in contact with the plurality of first active patterns and a surface in contact with the first gate line is a curved surface.

According to some aspects of the inventive concepts, there is provided a semiconductor device including a substrate including a first area and a second area, first and second fin-type active regions protruding on the substrate, a first channel region on the first fin-type active region and including a plurality of first active patterns extending in a first horizontal direction and a semiconductor material layer surrounding at least portions of the plurality of first active patterns, a first gate line covering the first channel region on the first fin-type active region, a pair of first inner spacers separated from each other in the first horizontal direction with the first gate line therebetween, a second channel region on the second fin-type active region and including a plurality of second active patterns extending in the first horizontal direction, a second gate line covering the second channel region on the second fin-type active region, a pair of first source/drain regions at both sides of the first gate line on the first fin-type active region, and a pair of second source/drain regions at both sides of the second gate line on the second fin-type active region, wherein the first fin-type active region is in the first area of the substrate, the second fin-type active region is in the second area of the substrate, a work function of the semiconductor material layer is different from a work function of the plurality of first active patterns, the semiconductor material layer surrounds a portion of the first gate line between two adjacent first active patterns and the pair of first inner spacers, and the first gate line is separated from the pair of first source/drain regions with the semiconductor material layer and the pair of first inner spacers therebetween.

### BRIEF DESCRIPTION OF THE DRAWINGS

Example embodiments of the inventive concepts will be more clearly understood from the following detailed description taken in conjunction with the accompanying drawings in which:

FIG. 1 is a layout diagram of a semiconductor device according to some example embodiments;

FIG. 2 is cross-sectional views taken along lines X1-X1′ and X2-X2′ of the semiconductor device of FIG. 1;

FIG. 3 is a magnified view of portion III of FIG. 2;

FIG. 4 is cross-sectional views taken along lines Y1-Y1′ and Y2-Y2′ of the semiconductor device of FIG. 1;

FIGS. 5 and 6 are cross-sectional views for describing a semiconductor device according to some example embodiments;

FIG. 7 is cross-sectional views for describing a semiconductor device according to some example embodiments;

FIG. 8 is a layout diagram of a semiconductor device according to some example embodiments;

FIGS. 9 and 10 are cross-sectional views for describing semiconductor devices according to some example embodiments, respectively;

FIG. 11 is a layout diagram of a semiconductor device according to some example embodiments;

FIGS. 12 and 13 are cross-sectional views for describing semiconductor devices according to some example embodiments, respectively;

FIGS. 14 to 18 are cross-sectional views for describing, in a process order, a method of fabricating a semiconductor device, according to some example embodiments; and

FIGS. 19 to 23 are cross-sectional views for describing, in a process order, a method of fabricating a semiconductor device, according to some example embodiments.

### DETAILED DESCRIPTION

The example embodiments may allow various kinds of change or modification and various changes in form, and some example embodiments are illustrated in drawings and described in detail. However, it is not intended that the example embodiments are limited to a specific disclosing form.

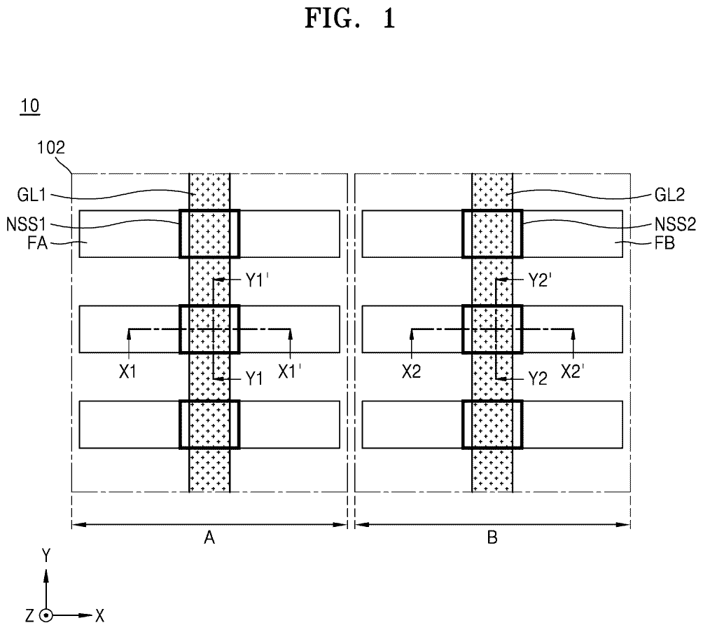

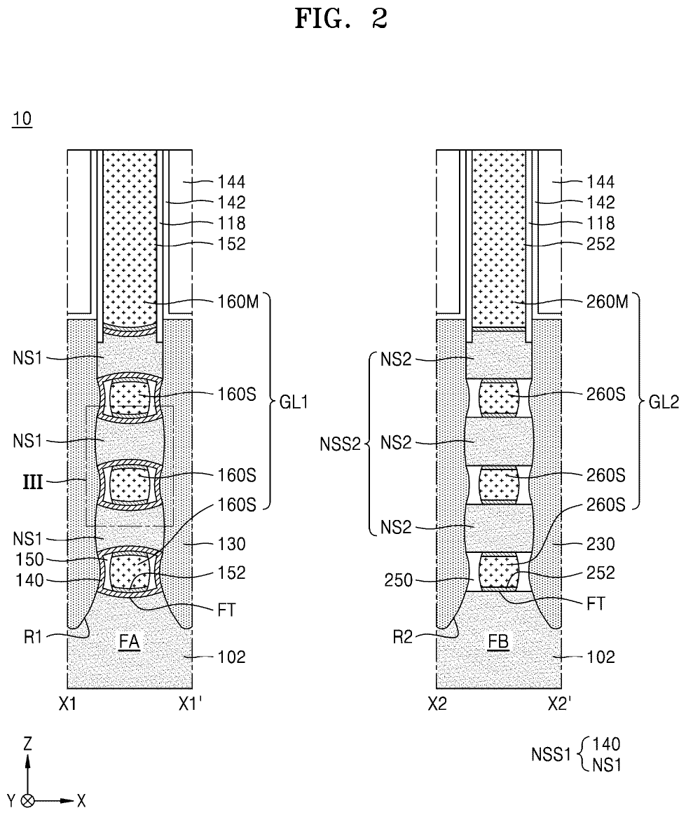

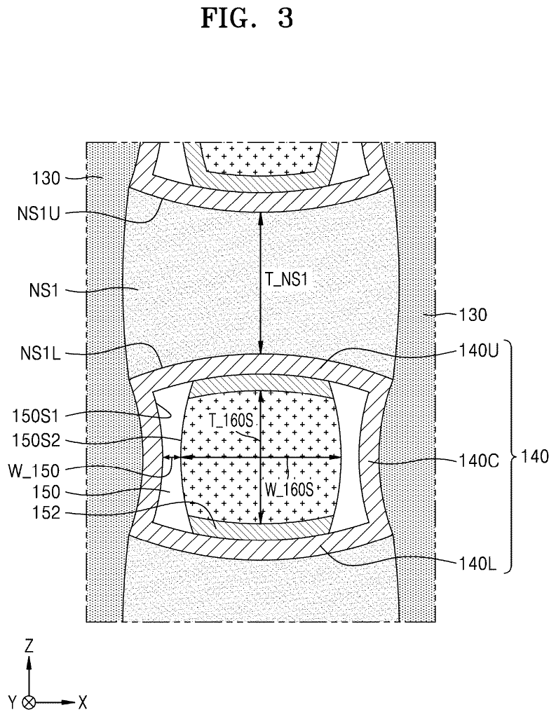

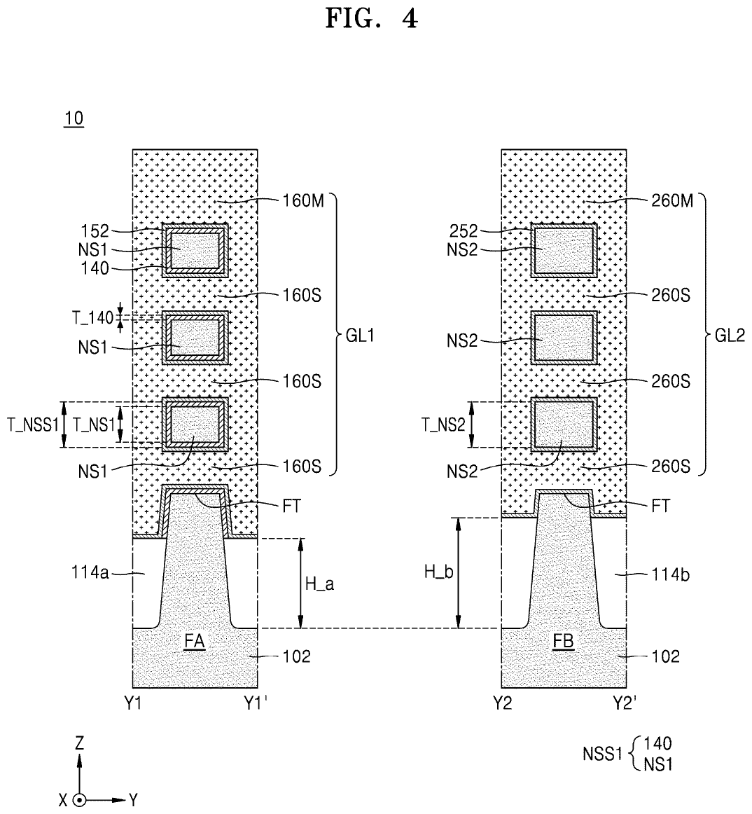

FIG. 1 is a layout diagram of a semiconductor device 10 according to some example embodiments. FIG. 2 is cross-sectional views taken along lines X1-X1′ and X2-X2′ of the semiconductor device 10 of FIG. 1. FIG. 3 is a magnified view of portion III of FIG. 2. FIG. 4 is cross-sectional views taken along lines Y1-Y1′ and Y2-Y2′ of the semiconductor device 10 of FIG. 1.

The semiconductor device 10 including a field-effect transistor having a gate-all-around (GAA) structure including a channel region in a nanowire or nanosheet shape and a gate surrounding the channel region is described with reference to FIGS. 1 to 4.

Referring to FIGS. 1 to 4, the semiconductor device 10 may include a substrate 102, a first fin-type active region FA, a second fin-type active region FB, a first channel region NSS1, a second channel region NSS2, a first gate line GL1, a second gate line GL2, a first source/drain region 130, and a second source/drain region 230.

The substrate 102 of the semiconductor device 10 may include a semiconductor, such as silicon (Si) or germanium (Ge), or a compound semiconductor, such as SiGe, silicon carbide (SiC), gallium arsenide (GaAs), indium arsenide (InAs), indium gallium arsenide (InGaAs), or indium phosphide (InP). The terms “SiGe”, “SiC”, “GaAs”, “InAs”, “InGaAs”, and “InP” used in the specification indicate materials including elements included in each term but are not chemical formulae indicating stoichiometric relationships. The substrate 102 may include a conductive region, for example, an impurity-doped well or an impurity-doped structure.

The substrate 102 may include a first area A and a second area B. Herein, the first area A may be connected to or separated from the second area B.

In some example embodiments, the first area A and the second area B may perform the same or a similar function (for example, a memory area, a logic area, etc.).

In some example embodiments, the first area A and the second area B may perform different functions. For example, the first area A may be a portion constituting a logic area and the second area B may be the other portion constituting the logic area. In some example embodiments, the first area A may be one of a memory area and a non-memory area and the second area B may be the other one of the memory area and the non-memory area. Herein, the memory area may include a static random access memory (SRAM) area, a dynamic RAM (DRAM) area, a magnetic RAM (MRAM) area, a resistive RAM (RRAM) area, a phase-change RAM (PRAM) area, or the like, and the non-memory area may include a logic area.

As shown in FIG. 2, the first fin-type active region FA and the first channel region NSS1 may be in the first area A of the semiconductor device 10. The first fin-type active region FA may protrude upward from the substrate 102 in a vertical direction (the Z direction) and extend long in a first horizontal direction (the X direction). The first channel region NSS1 may include a plurality of first active patterns NS1 and a semiconductor material layer 140. The first channel region NSS1 may be on the first fin-type active region FA.

The term “active pattern” used in the specification indicates a conductive structure having a cross-section that is substantially perpendicular to a current flowing direction. It should be understood that an active pattern includes a nanosheet and a nanowire.

The second fin-type active region FB and the second channel region NSS2 may be in the second area B of the semiconductor device 10. The second fin-type active region FB may protrude upward from the substrate 102 in the vertical direction (the Z direction) and extend long in the first horizontal direction (the X direction). The second channel region NSS2 may include a plurality of second active patterns NS2. The second channel region NSS2 may be on the second fin-type active region FB. The plurality of second active patterns NS2 may extend in the first horizontal direction (the X direction).

As shown in FIG. 4, a first device isolation layer 114a covering both side surfaces of the first fin-type active region FA may be in the first area A of the substrate 102, and a second device isolation layer 114b covering both side surfaces of the second fin-type active region FB may be in the second area B of the substrate 102. The first and second device isolation layers 114a and 114b may include an oxide layer, a nitride layer, or a combination thereof. Hereinafter, in the specification, a side surface along a flat to curved surface may be referred to as a sidewall, defined by sharp angles such as about or exactly 90 degrees, 75 degrees, etc.

In some example embodiments, the thickness of the first device isolation layer 114a may be a first thickness H_a and the thickness of the second device isolation layer 114b may be a second thickness H_b. Herein, the thicknesses of the first and second device isolation layers 114a and 114b indicate lengths in the vertical direction (the Z direction).

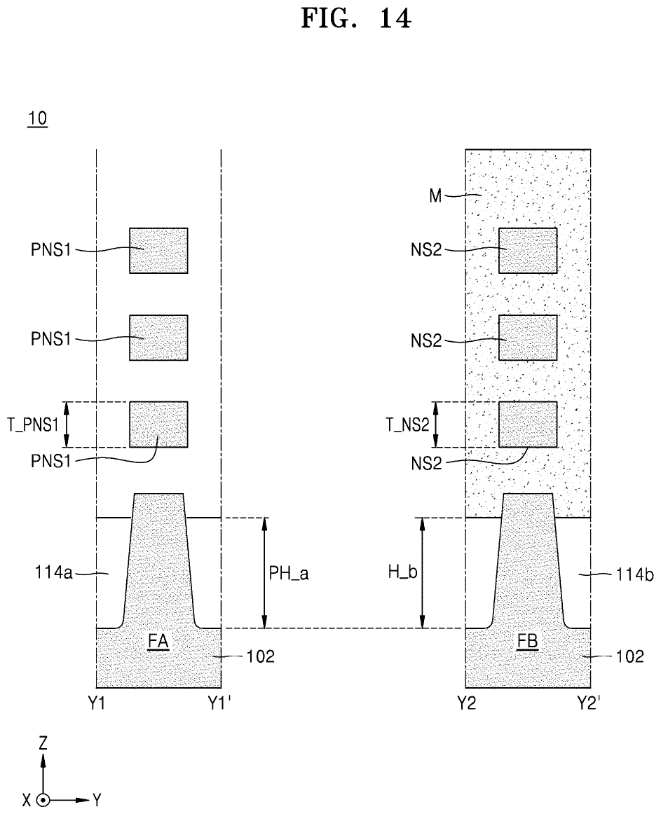

In some example embodiments, the first thickness H_a may be less than or equal to the second thickness H_b. In a process of fabricating the semiconductor device 10, if an etching process is performed on the first area A, the first thickness H_a may be less than the second thickness H_b. In a process of fabricating the semiconductor device 10, if an etching process is not performed on the first area A, the first thickness H_a may be substantially the same or the same as the second thickness H_b. The first thickness H_a and the second thickness H_b are described in detail below with reference to FIGS. 14 to 23.

As shown in FIGS. 1 to 4, in the first area A, the first gate line GL1 may be on the first fin-type active region FA. The first gate line GL1 may extend long in a second horizontal direction (the Y direction) that is perpendicular to the first horizontal direction (the X direction).

In a region in which the first fin-type active region FA intersects with the first gate line GL1, the first channel region NSS1 may be on the first fin-type active region FA. That is, the plurality of first active patterns NS1 of the first channel region NSS1 may be in the region in which the first fin-type active region FA intersects with the first gate line GL1. The plurality of first active patterns NS1 may overlap each other above the first fin-type active region FA in the vertical direction (the Z direction). That is, each of the plurality of first active patterns NS1 may have a different distance separated from the upper surface of the first fin-type active region FA in the vertical direction (the Z direction). Each of the plurality of first active patterns NS1 may face a fin top FT of the first fin-type active region FA at a position separated from the first fin-type active region FA in the vertical direction (the Z direction).

Although FIG. 1 shows that the planar cross-sectional shape of each of the plurality of first active patterns NS1 is approximately quadrangular, the planar cross-sectional shape is not limited thereto. Each of the plurality of first active patterns NS1 may have various planar shapes according to the planar shape of each of the first fin-type active region FA and the first gate line GL1. Some example embodiments illustrate a feature wherein one first channel region NSS1 and one first gate line GL1 are on one first fin-type active region FA. However, the number of first channel regions NSS1 and the number of first gate lines GL1 on one first fin-type active region FA are not particularly limited.

In some example embodiments, a thickness T_NS1 of each of the plurality of first active patterns NS1 may be selected within a range of about or exactly 2.5 nm to about or exactly 5 nm but is not limited thereto. Herein, the thickness T_NS1 of a first active pattern NS1 indicates the length of the first active pattern NS1 in the vertical direction (the Z direction). In some example embodiments, the plurality of first active patterns NS1 may have substantially the same or the same thickness. In some example embodiments, at least some of the plurality of first active patterns NS1 may have different thicknesses in the vertical direction (the Z direction).

The semiconductor material layer 140 may be between the first gate line GL1 and the plurality of first active patterns NS1 and between the first gate line GL1 and a pair of first source/drain regions 130. The semiconductor material layer 140 may surround portions of the first gate line GL1 between two adjacent first active patterns NS1. The semiconductor material layer 140 may have a shape surrounding the first gate line GL1 and a first gate dielectric layer 152.

In some example embodiments, when the semiconductor device 10 further includes a pair of first inner spacers 150, the semiconductor material layer 140 may be between the pair of first inner spacers 150 and the pair of first source/drain regions 130. At one side of the first gate line GL1, the first source/drain region 130 may be separated from a first inner spacer 150 with the semiconductor material layer 140 therebetween. The semiconductor material layer 140 may have a shape surrounding the pair of first inner spacers 150, the first gate dielectric layer 152, and the first gate line GL1.

The pair of first source/drain regions 130 may be separated from the first gate line GL1 with the semiconductor material layer 140 therebetween. The pair of first source/drain regions 130 may not be in contact with the first gate line GL1.

The first channel region NSS1 may include the plurality of first active patterns NS1 and the semiconductor material layer 140, wherein a first active pattern NS1 has a work function that is different from that of the semiconductor material layer 140. In some example embodiments, a material of the first active pattern NS1 may include Si and a material of the semiconductor material layer 140 may include SiGe. In some example embodiments, as a thickness T_140 of the semiconductor material layer 140 increases, the work function of the first active pattern NS1 may increase.

In some example embodiments, when the material of the semiconductor material layer 140 is SiGe, the Ge concentration of the semiconductor material layer 140 may be about or exactly 20% to about or exactly 60%. For example, the weight ratio of Ge in SiGe of the semiconductor material layer 140 may be about or exactly 20% to about or exactly 60%.

Although FIG. 1 shows that the substrate 102 is divided into two areas and the semiconductor material layer 140 is included in one area, the substrate 102 is not limited thereto and may be divided into three or more areas, wherein the semiconductor material layer 140 may be included in two or more areas. In this case, the Ge concentrations of the semiconductor material layers 140 included in different areas may be different from each other.

In some example embodiments, the thickness T_140 of the semiconductor material layer 140 may be about or exactly 1 nm to about or exactly 1.5 nm. The semiconductor material layer 140 may be conformally formed along the first source/drain region 130 and the first active pattern NS1. That is, the semiconductor material layer 140 may have a constant thickness. The shape of the semiconductor material layer 140 may vary according to the shapes of the first active pattern NS1 and the first source/drain region 130 which are in contact with the outer surface of the semiconductor material layer 140.

In some example embodiments, as shown in FIGS. 2 and 4, the plurality of first active patterns NS1 may have the same size in the first horizontal direction (the X direction) and/or the second horizontal direction (the Y direction). However, the plurality of first active patterns NS1 are not limited thereto, and at least some of the plurality of first active patterns NS1 may have different sizes in the first horizontal direction (the X direction) and/or the second horizontal direction (the Y direction).

As shown in FIG. 2, in the first area A, a pair of recesses R1 may be formed in the first fin-type active region FA. The vertical level of the lowermost surface of each of the pair of recesses R1 may be lower than the vertical level of the fin top FT of the first fin-type active region FA. The term “vertical level” used in the specification indicates a distance separated from the lower surface of the substrate 102 in the vertical direction (the Z direction).

The pair of first source/drain regions 130 may be in the pair of recesses R1, respectively. The pair of first source/drain regions 130 may be formed at both sides of the first gate line GL1 on the first fin-type active region FA by being separated from each other in the first horizontal direction (the X direction). Each of the pair of first source/drain regions 130 may have a sidewall facing the plurality of first active patterns NS1 included in the first channel region NSS1 adjacent thereto. That is, each of the pair of first source/drain regions 130 may be in contact with the plurality of first active patterns NS1 included in the first channel region NSS1 adjacent thereto.

The pair of first source/drain regions 130 may include an epitaxially grown semiconductor layer. In some example embodiments, the pair of first source/drain regions 130 may include a group IV element semiconductor, a group IV-IV compound semiconductor, or a combination thereof. In some example embodiments, each of the pair of first source/drain regions 130 may include an Si layer doped with an n-type dopant, a SiC layer doped with the n-type dopant, or an SiGe layer doped with a p-type dopant. The n-type dopant may be selected from among phosphorous (P), arsenic (As), and antimony (Sb). The p-type dopant may be selected from among boron (B) and gallium (Ga). However, the dopants above are merely examples and the present disclosure is not limited thereto.

The first gate line GL1 may extend long on the first fin-type active region FA in the second horizontal direction (the Y direction) and surround each of the plurality of first active patterns NS1 by covering the first channel region NSS1. The first gate line GL1 may include a main gate portion 160M and a plurality of sub-gate portions 160S. The main gate portion 160M may extend in the second horizontal direction (the Y direction) while covering the upper surface of the first channel region NSS1. The plurality of sub-gate portions 160S may be integrally connected to the main gate portion 160M and respectively disposed between the plurality of first active patterns NS1 and between the first active pattern NS1 and the first fin-type active region FA. The thickness of each of the plurality of sub-gate portions 160S may be less than the thickness of the main gate portion 160M.

The first gate line GL1 may include a metal, metal nitride, metal carbide, or a combination thereof. The metal may be selected from among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from among titanium nitride (TiN) and tantalum nitride (TaN). The metal carbide may be titanium aluminum carbide (TiAlC). However, the material constituting the first gate line GL1 is not limited thereto.

The first gate dielectric layer 152 may be between the first active pattern NS1 and the first gate line GL1. The first gate dielectric layer 152 may cover the lower surface of the main gate portion 160M in the first gate line GL1.

In some example embodiments, the first gate dielectric layer 152 may include a stacked structure of an interface layer and a high-k layer. The interface layer may include a low-k material layer, for example, an Si oxide layer or an Si oxynitride layer, of which the dielectric constant is 9 or less or a combination thereof. In some example embodiments, the interface layer may be omitted. The high-k layer may include a material having a dielectric constant that is greater than that of the Si oxide layer. For example, the high-k layer may have a dielectric constant of about or exactly 10 to about or exactly 25. The high-k layer may include Hf oxide but is not limited thereto.

The pair of first inner spacers 150 may be between two adjacent first active patterns NS1. Particularly, the pair of first inner spacers 150 may be separated from each other in the first horizontal direction (the X direction) and be at both sides of a sub-gate portion 160S between two adjacent first active patterns NS1. The sub-gate portion 160S may be at one side of each of the pair of first inner spacers 150 and the semiconductor material layer 140 may be at the other side thereof.

Each of the pair of first inner spacers 150 may be in contact with the sub-gate portion 160S at the one side thereof and be in contact with the semiconductor material layer 140 at the other side thereof.

Each of the pair of first inner spacers 150 may include silicon nitride (SiN), silicon oxide (SiO), silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. The terms “SiN”, “SiO”, “SiCN”, “SiBN”, “SiON”, “SiOCN”, “SiBCN”, and “SiOC” used in the specification indicate materials including elements included in each term but are not chemical formulae indicating stoichiometric relationships.

Hereinafter, the shapes of the first channel region NSS1, the first gate line GL1, and the pair of first inner spacers 150 are described in detail in a fabricating order with reference to FIG. 3.

An etching process may be performed on the plurality of first active patterns NS1 separated from each other on the first fin-type active region FA in the vertical direction (the Z direction). In some example embodiments, wet etching may be performed in spaces in which the plurality of first active patterns NS1 are separated from each other, to etch an upper surface NS1U and a lower surface NS1L of each of the plurality of first active patterns NS1, thereby decreasing the thickness T_NS1 of each of the plurality of first active patterns NS1. By the etching process, the upper surface NS1U and the lower surface NS1L of each of the plurality of first active patterns NS1 may be curved surfaces recessed inward. That is, the thickness T_NS1 of each of the plurality of first active patterns NS1 may decrease (for example, gradually decrease or decrease at a desired rate) toward the center of the first active pattern NS1.

After forming the first active pattern NS1, the semiconductor material layer 140 may be formed by a deposition process or an epitaxial process. The semiconductor material layer 140 may be grown to correspond to the upper surface NS1U and the lower surface NS1L of each of the plurality of first active patterns NS1 and the sidewalls of the pair of first source/drain regions 130. That is, the semiconductor material layer 140 may be conformally formed along the upper surface NS1U and the lower surface NS1L of each of the plurality of first active patterns NS1 and the sidewalls of each of the pair of first source/drain regions 130. The semiconductor material layer 140 may have a constant thickness.

In some example embodiments, in the semiconductor material layer 140, an upper wall 140U and a lower wall 140L may have a shape protruding outward and both sidewalls 140C may have a shape recessed inward. That is, in a region in which the semiconductor material layer 140 is in contact with a first active pattern NS1, the semiconductor material layer 140 may have a shape protruding toward the first active pattern NS1. In a region in which the semiconductor material layer 140 is in contact with each of the pair of first source/drain regions 130, the semiconductor material layer 140 may have a shape recessed toward the first gate line GL1.

In some example embodiments, in the semiconductor material layer 140, a surface in contact with the first active pattern NS1 and/or a surface in contact with the gate line GL1 may be a curved surface.

After forming the semiconductor material layer 140, the pair of first inner spacers 150 separated from each other in the first horizontal direction (the X direction) may be formed by depositing an insulating material in an empty space remaining between two adjacent first active patterns NS1 and starting etching from the central point of the remaining empty space.

Hereinafter, among both sidewalls 150S1 and 150S2 in each of the pair of first inner spacers 150, a sidewall in contact with the semiconductor material layer 140 is a first sidewall 150S1 and a sidewall in contact with the first gate line GL1 is a second sidewall 150S2. In each of the pair of first inner spacers 150, the shape of the first sidewall 150S1 may correspond to the shape of the sidewall 140C of the semiconductor material layer 140 and the shape of the second sidewall 150S2 may be a curved shape recessed toward the first sidewall 150S1 by an etching process.

That is, in each of the pair of first inner spacers 150, the first and second sidewalls 150S1 and 150S2 may be curved surfaces recessed inward. In each of the pair of first inner spacers 150, the first sidewall 150S1 may have a shape recessed toward the first gate line GL1 and the second sidewall 150S2 may have a shape recessed toward the first source/drain region 130.

Each of the pair of first inner spacers 150 may have a shape in which a width W_150 in the first horizontal direction (the X direction) decreases (for example, gradually decrease or decrease at a desired rate) toward the center of each of the pair of first inner spacers 150. In some example embodiments, each of the pair of first inner spacers 150 may have the width W_150 in the first horizontal direction (the X direction) that is the least at an intermediate height of each of the pair of first inner spacers 150.

After forming the pair of first inner spacers 150, the first gate line GL1 may be formed. In a process of fabricating the first gate line GL1, a sub-gate portion 160S may be formed by filling a first gate metal in a space in which the pair of first inner spacers 150 are separated from each other. Accordingly, the sub-gate portion 160S may have sidewalls of which the shapes are determined by the shapes of the pair of first inner spacers 150.

Accordingly, both side surfaces of the sub-gate portion 160S may be curved surfaces protruding outward. That is, both the side surfaces of the sub-gate portion 160S may have a shape protruding toward the pair of first inner spacers 150. In some example embodiments, a width W_160S of the sub-gate portion 160S in the first horizontal direction (the X direction) and/or the second horizontal direction (the Y direction) may increase (for example, gradually increase or increase at a desired rate) toward the center of the sub-gate portion 160S.

Each of the upper and lower surfaces of the sub-gate portion 160S may have a shape protruding outward. That is, each of the upper and lower surfaces of the sub-gate portion 160S may have a shape protruding toward an adjacent first active pattern NS1. In some example embodiments, a thickness T_160S of the sub-gate portion 160S may increase (for example, gradually increase or increase at a desired rate) toward the center of the sub-gate portion 160S. That is, the upper surface of the sub-gate portion 160S may have a shape in which a distance to the lower surface of the sub-gate portion 160S decreases as the upper surface approaches an edge of the sub-gate portion 160S.

As shown in FIGS. 1 to 4, in the second area B, the second gate line GL2 may be on the second fin-type active region FB. The second gate line GL2 may extend long in the second horizontal direction (the Y direction).

In a region in which the second fin-type active region FB intersects with the second gate line GL2, the second channel region NSS2 may be on the second fin-type active region FB. The second channel region NSS2 may include the plurality of second active patterns NS2. The plurality of second active patterns NS2 may overlap each other above the second fin-type active region FB in the vertical direction (the Z direction).

Although FIG. 1 shows that the planar cross-sectional shape of each of the plurality of second active patterns NS2 is approximately quadrangular, the planar cross-sectional shape is not limited thereto. Each of the plurality of second active patterns NS2 may have various planar shapes according to the planar shape of each of the second fin-type active region FB and the second gate line GL2.

Some example embodiments illustrate a feature wherein one second channel region NSS2 and one second gate line GL2 are on one second fin-type active region FB. However, the number of second channel regions NSS2 and the number of second gate lines GL2 on one second fin-type active region FB are not particularly limited.

In some example embodiments, a material of a second active pattern NS2 may be substantially the same or the same as the material of the first active pattern NS1. That is, the second active pattern NS2 may have the same work function as the first active pattern NS1. However, because both the first active pattern NS1 and the semiconductor material layer 140 in the first channel region NSS1 become an electron moving passage and the second active pattern NS2 in the second channel region NSS2 becomes an electron moving passage, the first channel region NSS1 may have a work function that is different from that of the second channel region NSS2.

In some example embodiments, a thickness T_NS2 of each of the plurality of second active patterns NS2 may be selected within a range of about or exactly 4 nm to about or exactly 6 nm but is not limited thereto. In some example embodiments, the plurality of second active patterns NS2 may have substantially the same or the same thickness. In some example embodiments, at least some of the plurality of second active patterns NS2 may have different thicknesses in the vertical direction (the Z direction).

In some example embodiments, the thickness T_NS2 of the second active pattern NS2 may be greater than the thickness T_NS1 of the first active pattern NS1. The thickness T_NS2 of the second active pattern NS2 may be substantially the same or the same as a sum T_NSS1 of the thickness T_NS1 of the first active pattern NS1 and the thickness T_140 of the semiconductor material layer 140. That is, the thickness T_140 of the semiconductor material layer 140 may be the difference between the thickness T_NS1 of the first active pattern NS1 and the thickness T_NS2 of the second active pattern NS2.

In some example embodiments, as shown in FIGS. 2 and 4, the plurality of second active patterns NS2 may have the same size in the first horizontal direction (the X direction) and/or the second horizontal direction (the Y direction). However, the plurality of second active patterns NS2 are not limited thereto, and at least some of the plurality of second active patterns NS2 may have different sizes in the first horizontal direction (the X direction) and/or the second horizontal direction (the Y direction).

As shown in FIG. 2, in the second area B, a pair of recesses R2 may be formed in the second fin-type active region FB. The vertical level of the lowermost surface of each of the pair of recesses R2 may be lower than the vertical level of the fin top FT of the second fin-type active region FB.

A pair of second source/drain regions 230 may be in the pair of recesses R2, respectively. The pair of second source/drain regions 230 may be formed at both sides of the second gate line GL2 on the second fin-type active region FB by being separated from each other in the first horizontal direction (the X direction). Each of the pair of second source/drain regions 230 may have a sidewall facing the plurality of second active patterns NS2 included in the second channel region NSS2 adjacent thereto. That is, each of the pair of second source/drain regions 230 may be in contact with the plurality of second active patterns NS2 included in the second channel region NSS2 adjacent thereto. A material of the pair of second source/drain regions 230 is generally the same as described for the material of the pair of first source/drain regions 130.

In some example embodiments, when the pair of second source/drain regions 230 are doped with a p-type dopant, the pair of first source/drain regions 130 may be doped with an n-type dopant. That is, because the dopant doped in the first source/drain region 130 belongs to a group that is different from a group to which the dopant doped in the second source/drain region 230 belongs, in the semiconductor device 10, the threshold voltage in the first area A may be different from the threshold voltage in the second area B.

The second gate line GL2 may extend long on the second fin-type active region FB in the second horizontal direction (the Y direction) and surround each of the plurality of second active patterns NS2 by covering the second channel region NSS2. The second gate line GL2 may include a main gate portion 260M and a plurality of sub-gate portions 260S.

The main gate portion 260M may extend in the second horizontal direction (the Y direction) while covering the upper surface of the second channel region NSS2. The plurality of sub-gate portions 260S may be integrally connected to the main gate portion 260M and respectively disposed between the plurality of second active patterns NS2 and between the second active pattern NS2 and the second fin-type active region FB. The thickness of each of the plurality of sub-gate portions 260S may be less than the thickness of the main gate portion 260M. A material of the second gate line GL2 is generally the same as described for the material of the first gate line GL1.

A second gate dielectric layer 252 may be between the second active pattern NS2 and the second gate line GL2. The second gate dielectric layer 252 may cover the lower surface and the side walls of the main gate portion 260M in the second gate line GL2.

In some example embodiments, the second gate dielectric layer 252 may include a stacked structure of an interface layer and a high-k layer. Materials of the interface layer and the high-k layer in the second gate dielectric layer 252 are generally the same as described for the materials of the interface layer and the high-k layer in the first gate line GL1.

A pair of second inner spacers 250 may be between two adjacent second active patterns NS2. Particularly, the pair of second inner spacers 250 may be separated from each other in the first horizontal direction (the X direction) and be at both sides of the second gate line GL2 between two adjacent second active patterns NS2. The pair of second inner spacers 250 may be separated from each other with the second gate line GL2 therebetween. Each of the pair of second inner spacers 250 may be in contact with the second source/drain region 230 at one side thereof and be in contact with the second gate dielectric layer 252 at the other side thereof.

Each of the pair of second inner spacers 250 may include SiN, SiO, SiCN, SiBN, SION, SiOCN, SiBCN, SiOC, or a combination thereof.

In the first area A and the second area B, a plurality of insulating spacers 118 may cover both sidewalls of each of the first gate line GL1 and the second gate line GL2.

In the first area A, the plurality of insulating spacers 118 may cover both sidewalls of the main gate portion 160M of the first gate line GL1 on the upper surface of the first channel region NSS1.

In the second area B, the plurality of insulating spacers 118 may cover both sidewalls of the main gate portion 260M of the second gate line GL2 on the upper surface of the second channel region NSS2.

Each of the plurality of insulating spacers 118 may include SiN, SiO, SiCN, SiBN, SION, SiOCN, SiBCN, SiOC, or a combination thereof.

Each of the pair of first source/drain regions 130 and the pair of second source/drain regions 230 may include a portion overlapping an insulating spacer 118 in the vertical direction (the Z direction). For example, the first horizontal directional (X directional) width of a portion of the first source/drain region 130 overlapping the insulating spacer 118 in the vertical direction (the Z direction) may be selected within a range of about or exactly 0 nm to about or exactly 4 nm but is not limited thereto.

In the first area A and the second area B, each of the first source/drain region 130, the second source/drain region 230, and the insulating spacer 118 may be covered by an insulating liner 142. The insulating liner 142 may include SiN, SiO, SiCN, SiBN, SION, SIOCN, SiBCN, SiOC, or a combination thereof. In some example embodiments, the insulating liner 142 may be omitted. An inter-gate insulating layer 144 may be on the insulating liner 142. The inter-gate insulating layer 144 may include a SiN layer, a SiO layer, SiON, SiOCN, or a combination thereof. When the insulating liner 142 is omitted, the inter-gate insulating layer 144 may be in contact with the first source/drain region 130 and the second source/drain region 230.

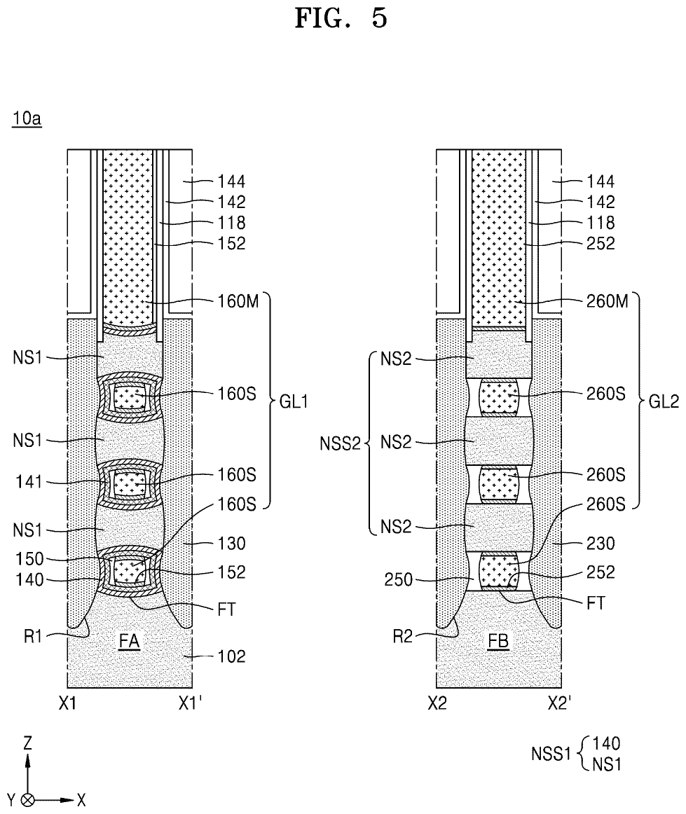

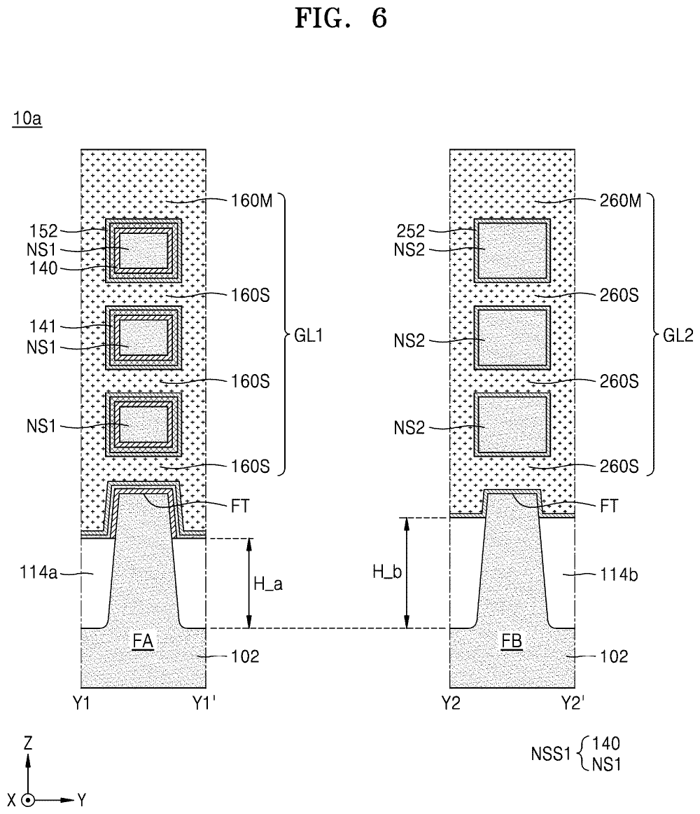

FIGS. 5 and 6 are cross-sectional views for describing a semiconductor device 10a according to some example embodiments.

Referring to FIGS. 5 and 6, the semiconductor device 10a may include the substrate 102, the first fin-type active region FA, the second fin-type active region FB, the first channel region NSS1, the second channel region NSS2, the first gate line GL1, the second gate line GL2, the first source/drain region 130, the second source/drain region 230, and a semiconductor cap 141.

Hereinafter, a description made for the semiconductor device 10 of FIG. 2 is omitted, and differences between the semiconductor device 10 of FIG. 2 and the semiconductor device 10a of FIG. 5 are mainly described. For example, the semiconductor device 10a of FIG. 5 may further include the semiconductor cap 141 in addition to the semiconductor device 10 of FIG. 2.

As shown in FIG. 5, the semiconductor cap 141 of the semiconductor device 10a may surround the first gate line GL1 and the pair of first inner spacers 150. The semiconductor cap 141 may be formed along the surface of the semiconductor material layer 140. That is, the semiconductor cap 141 may be between the semiconductor material layer 140 and the pair of first inner spacers 150 and between the semiconductor material layer 140 and the first gate line GL1.

In some example embodiments, the semiconductor cap 141 may be formed in an operation after forming the semiconductor material layer 140 and before forming the pair of first inner spacers 150. In this operation, the semiconductor cap 141 may be conformally formed along the surface of the semiconductor material layer 140.

That is, the upper and lower walls of the semiconductor cap 141 may be formed to correspond to the shapes of the upper and lower walls of the semiconductor material layer 140, respectively. Both sidewalls of the semiconductor cap 141 may be formed to correspond to the shapes of both sidewalls of the semiconductor material layer 140, respectively.

In some example embodiments, the semiconductor cap 141 may include a semiconductor, such as Si or Ge, or a compound semiconductor, such as SiGe, SiC, GaAs, InAs, InGaAs, or InP. The work function of the semiconductor cap 141 may be different from the work function of the semiconductor material layer 140 and the same as the work function of the first active pattern NS1. That is, when the material of the first active pattern NS1 is Si and the material of the semiconductor material layer 140 is SiGe, a material of the semiconductor cap 141 may be Si.

As shown in FIG. 6, a sum of the thickness of the semiconductor cap 141, the thickness of the semiconductor material layer 140, and the thickness of the first active pattern NS1 may be substantially the same or the same as the thickness of the second active pattern NS2.

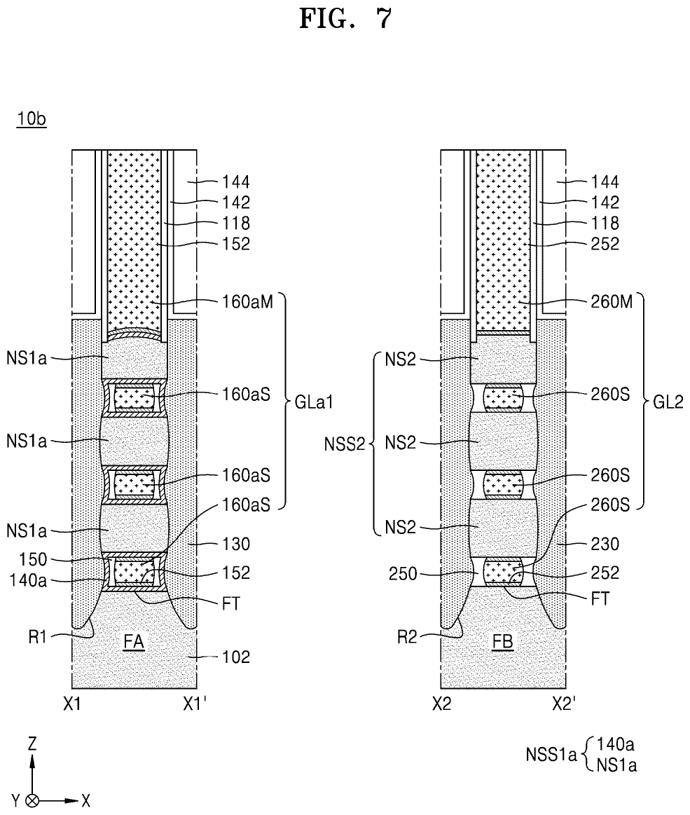

FIG. 7 is cross-sectional views for describing a semiconductor device 10b according to some example embodiments.

Referring to FIG. 7, the semiconductor device 10b may include the substrate 102, the first fin-type active region FA, the second fin-type active region FB, a first channel region NSS1a, the second channel region NSS2, a first gate line GLa1, the second gate line GL2, the first source/drain region 130, and the second source/drain region 230.

Hereinafter, a description made for the semiconductor device 10 of FIG. 2 is omitted, and differences between the semiconductor device 10 of FIG. 2 and the semiconductor device 10b of FIG. 7 are mainly described. The semiconductor device 10b of FIG. 7 substantially differs from the semiconductor device 10 of FIG. 2 with respect to the shapes of the first channel region NSS1a and the first gate line GLa1.

Through a process of fabricating the semiconductor device 10b, the shapes of the first channel region NSS1a and the first gate line GLa1 are particularly described.

Unlike the process of fabricating the semiconductor device 10, which has been described with reference to FIG. 3, a semiconductor material layer 140a may be formed in spaces in which a plurality of first active patterns NS1a are separated from each other, without an etching process on the plurality of first active patterns NS1a in the first channel region NSS1a. Accordingly, the upper and lower surfaces of a first active pattern NS1a may be flat. That is, the upper and lower surfaces of the first active pattern NS1a may have a curveless shape. The semiconductor material layer 140a may be conformally formed on the upper and lower surfaces of the first active pattern NS1a.

The center of a sidewall of the semiconductor material layer 140a may have a shape recessed toward a sub-gate portion 160aS. The pair of first inner spacers 150 may have both curved side surfaces recessed inward and have flat upper and lower surfaces. The sub-gate portion 160aS surrounded by the pair of first inner spacers 150 and the semiconductor material layer 140a may have curved side surfaces protruding outward and have flat upper and lower surfaces.

In some example embodiments, the lower surface of a main gate portion 160aM may have a curved surface recessed upward. In a process of forming the semiconductor material layer 140a on the upper surface of the uppermost first active pattern NS1a, the upper surface of the semiconductor material layer 140a may be formed to protrude upward. The lower surface of the main gate portion 160aM may be formed to correspond to the upper surface of the semiconductor material layer 140a, wherein the center of the lower surface of the main gate portion 160aM has a shape recessed upward.

Unlike the process of fabricating the semiconductor device 10, which has been described with reference to FIG. 3, a deposition process may be performed on the second active pattern NS2 in the second channel region NSS2. Particularly, before performing a deposition process on the second active pattern NS2, the first active pattern NS1a may have substantially the same or the same thickness as the second active pattern NS2. After performing a deposition process on the second active pattern NS2, the second active pattern NS2 may have a deposition thickness added by the thickness of the semiconductor material layer 140a. That is, a deposition process may be performed on the second active pattern NS2 so that the thickness of the second active pattern NS2 is a sum of the thickness of the semiconductor material layer 140a and the thickness of the first active pattern NS1a.

However, an order of forming the semiconductor material layer 140a and the second active pattern NS2 is not limited thereto, a process of forming the semiconductor material layer 140a after performing a deposition process on the second active pattern NS2 may be performed.

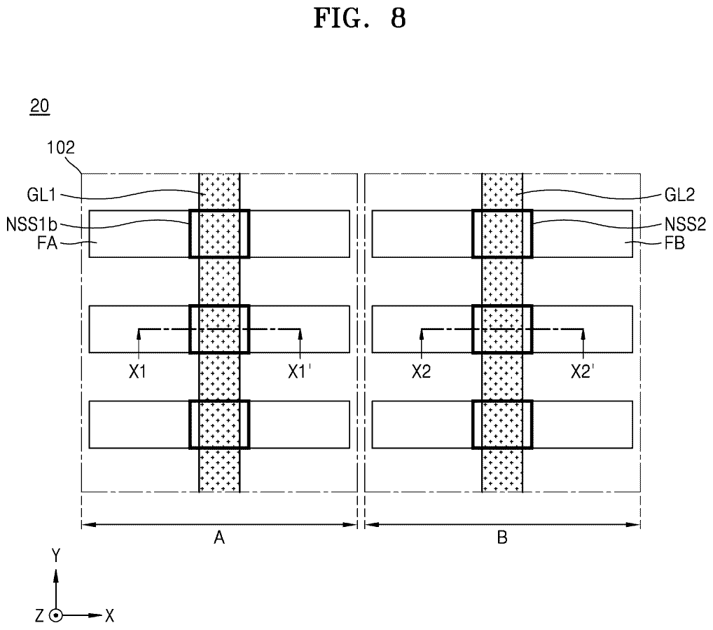

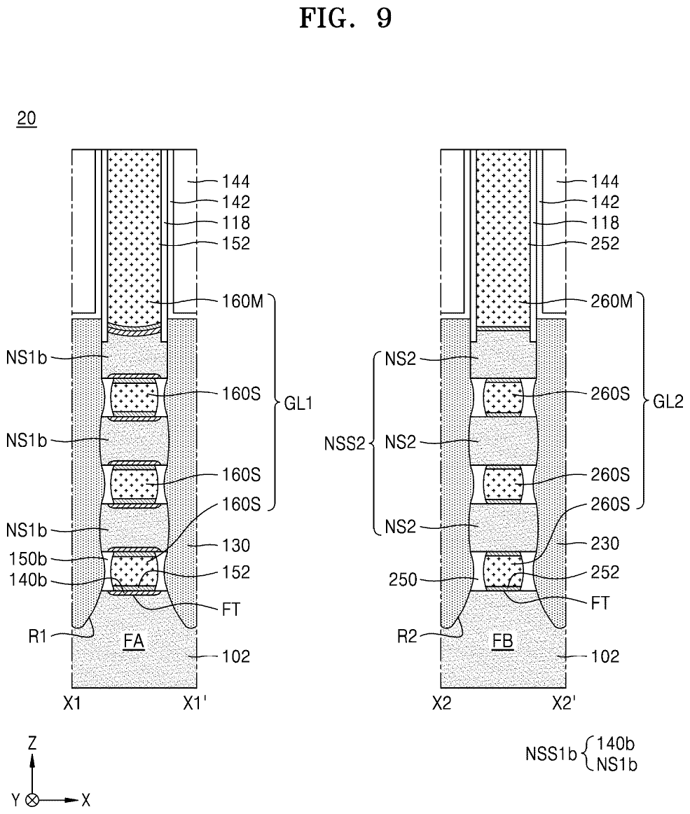

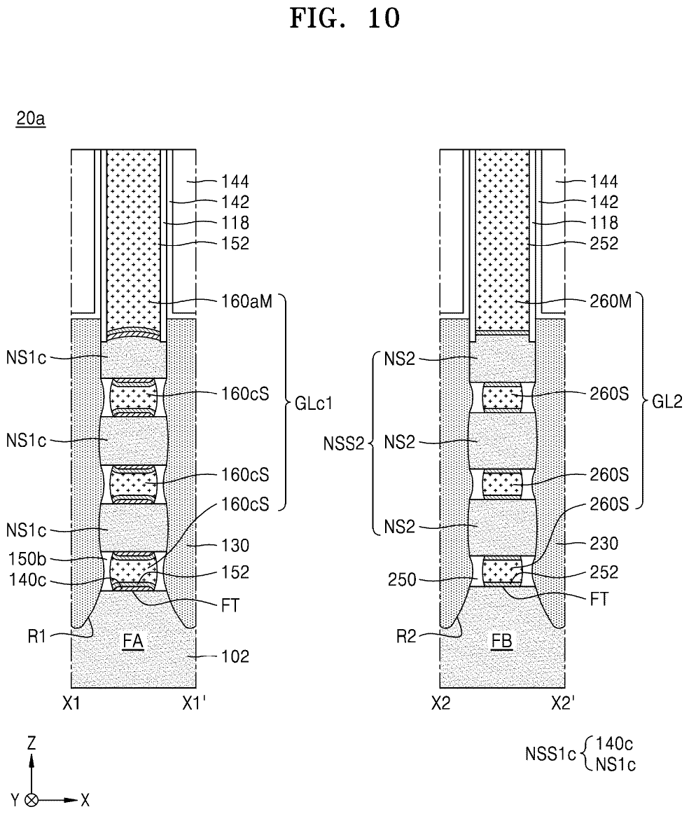

FIG. 8 is a layout diagram of a semiconductor device 20 according to some example embodiments. FIGS. 9 and 10 are cross-sectional views for describing semiconductor devices 20 and 20a according to some example embodiments, respectively.

Referring to FIGS. 8 and 9, the semiconductor device 20 may include the substrate 102, the first fin-type active region FA, the second fin-type active region FB, a first channel region NSS1b, the second channel region NSS2, the first gate line GL1, the second gate line GL2, the first source/drain region 130, and the second source/drain region 230.

Particularly, in the semiconductor devices 20 and 20a of FIGS. 8 to 10, a pair of first inner spacers 150b and the pair of second inner spacers 250 are formed before forming semiconductor material layers 140b and 140c. Hereinafter, a description made for the semiconductor device 10 of FIG. 2 is omitted, and differences between the semiconductor device 10 of FIG. 2 and the semiconductor devices 20 and 20a of FIGS. 8 to 10 are mainly described.

A portion of a first active pattern NS1b in the first channel region NSS1b may be in contact with a first inner spacer 150b. The first inner spacer 150b may be in contact with the first source/drain region 130 at one side thereof and be in contact with a sub-gate portion 160S at the other side thereof. That is, the first inner spacer 150b may be between the first source/drain region 130 and the sub-gate portion 160S. The first inner spacer 150b may have both curved side surfaces recessed inward and have flat upper and lower surfaces.

FIG. 9 particularly illustrates some example embodiments in which the semiconductor material layer 140b is formed after etching the first active pattern NS1b, wherein the upper and lower surfaces of the first active pattern NS1b have a shape in which the centers thereof are recessed inward. By forming the semiconductor material layer 140b in a space obtained by etching the first active pattern NS1b, one surface of the semiconductor material layer 140b in contact with the first active pattern NS1b may have a curved surface protruding outward.

FIG. 10 particularly illustrates some example embodiments in which the semiconductor material layer 140c is formed without an etching process on a first active pattern NS1c, wherein the upper and lower surfaces of the first active pattern NS1c are curve-less flat surfaces. In some example embodiments, the semiconductor material layer 140c formed between two adjacent first active patterns NS1c may include a curved surface. A surface of the semiconductor material layer 140c in contact with a first gate line GLc1 may be a curved surface protruding outward.

Accordingly, the upper and lower surfaces of a sub-gate portion 160cS formed inside the semiconductor material layer 140c may be curved surfaces recessed inward. In other words, the sub-gate portion 160cS may have the upper and lower surfaces recessed inward and have side surfaces protruding outward.

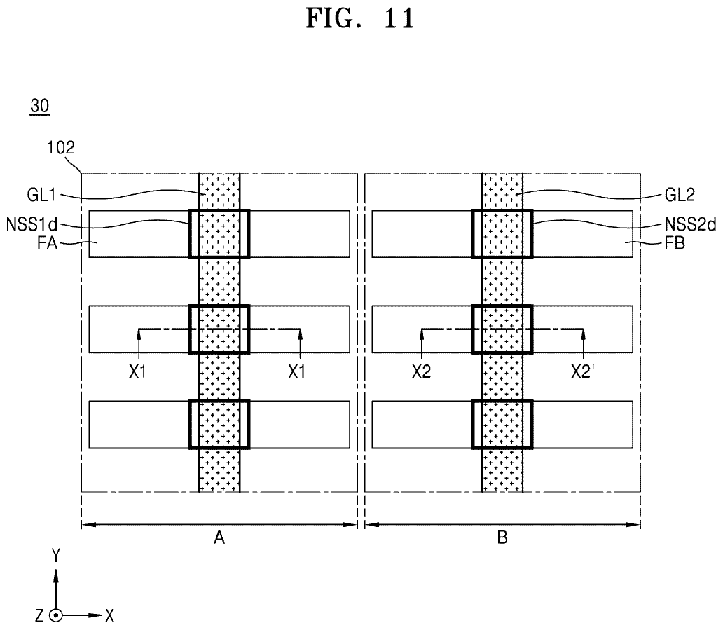

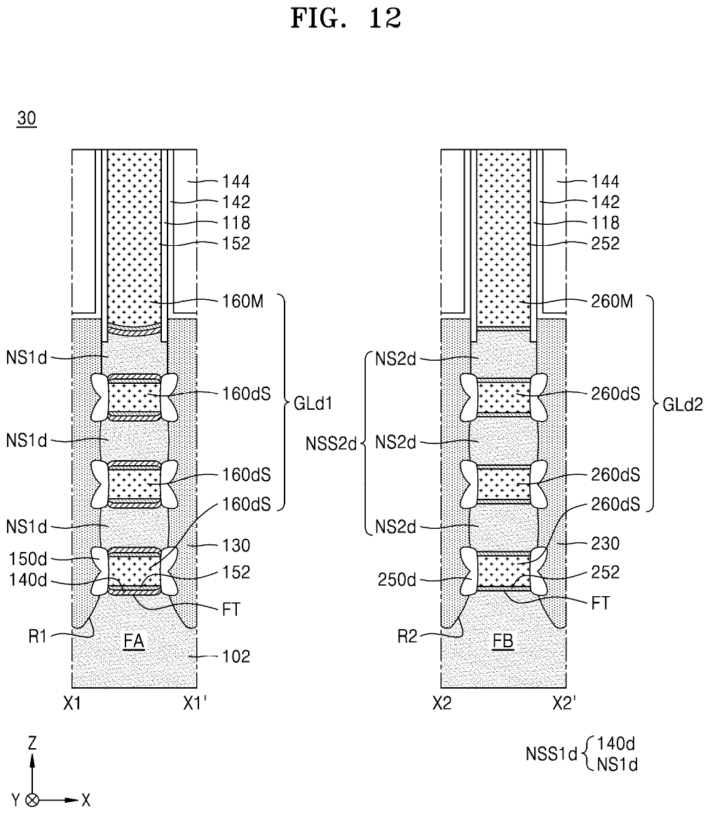

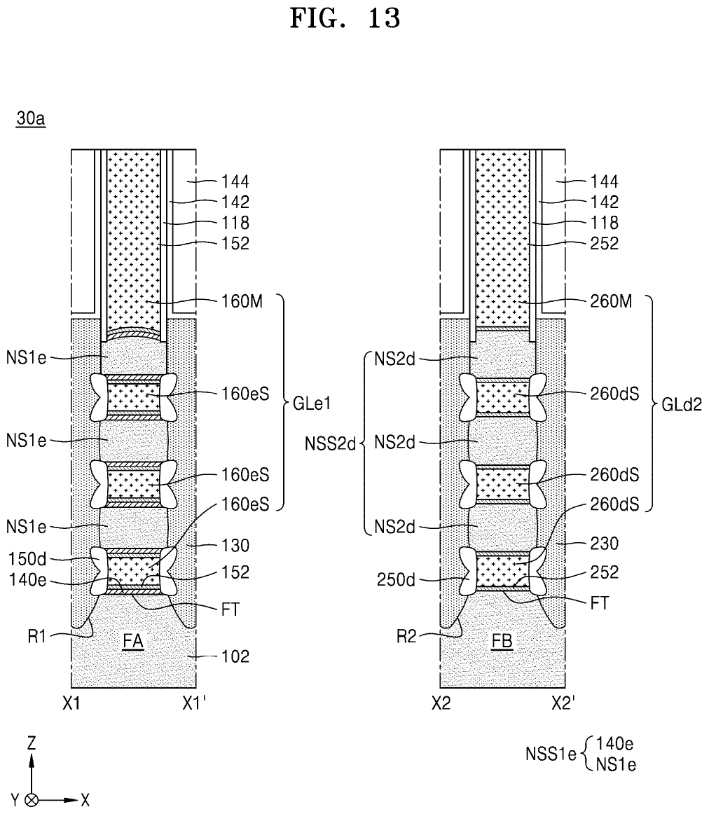

FIG. 11 is a layout diagram of a semiconductor device 30 according to some example embodiments. FIGS. 12 and 13 are cross-sectional views for describing semiconductor devices 30 and 30a according to some example embodiments, respectively.

Referring to FIGS. 11 and 12, the semiconductor device 30 may include the substrate 102, the first fin-type active region FA, the second fin-type active region FB, a first channel region NSS1d, a second channel region NSS2d, a first gate line GLd1, a second gate line GLd2, the first source/drain region 130, and the second source/drain region 230.

Particularly, in the semiconductor devices 30 and 30a of FIGS. 11 to 13, a first inner spacer 150d and a second inner spacer 250d are formed before forming semiconductor material layers 140d and 140e. Hereinafter, a description made for the semiconductor device 10 of FIG. 2 is omitted, and differences between the semiconductor device 10 of FIG. 2 and the semiconductor devices 30 and 30a of FIGS. 11 to 13 are mainly described.

In the semiconductor device 30 of FIGS. 11 and 12, the first and second inner spacers 150d and 250d are first formed in a state in which a preliminary gate line is filled between a plurality of first active patterns NS1d and between a plurality of second active patterns NS2d. Accordingly, portions of the first and second inner spacers 150d and 250d may be surrounded by the first and second source/drain regions 130 and 230, respectively.

A sidewall of the first inner spacer 150d in contact with the first gate line GLd1 may have a shape in which the center of the sidewall protrudes toward the first gate line GLd1. That is, the sidewall of the first inner spacer 150d in contact with the first gate line GLd1 may have a shape protruding outward.

FIG. 12 particularly illustrates some example embodiments in which the semiconductor material layer 140d is formed after etching a first active pattern NS1d, wherein the upper and lower surfaces of the first active pattern NS1d may have a shape in which the centers thereof are recessed inward. By forming the semiconductor material layer 140d in a space obtained by etching the first active pattern NS1d, one surface of the semiconductor material layer 140d in contact with the first active pattern NS1d may have a curved surface protruding outward.

Accordingly, the upper and lower surfaces of a sub-gate portion 160dS formed inside the semiconductor material layer 140d may be curved surfaces protruding outward. In other words, the sub-gate portion 160dS may have the upper and lower surfaces protruding outward and have side surfaces recessed inward.

FIG. 13 particularly illustrates some example embodiments in which the semiconductor material layer 140e is formed without an etching process on a first active pattern NS1e, wherein the upper and lower surfaces of the first active pattern NS1e are curve-less flat surfaces. In some example embodiments, one surface in contact with the first active pattern NS1e among the surfaces of the semiconductor material layer 140e formed between two adjacent first active patterns NS1e may be a flat surface in parallel to the upper and lower surfaces of the first active pattern NS1e.

Accordingly, the upper and lower surfaces of a sub-gate portion 160eS formed inside the semiconductor material layer 140e may be flat surfaces or curved surfaces recessed inward. In other words, the sub-gate portion 160eS may have the upper and lower surfaces flat or recessed inward and have side surfaces recessed inward.

A sidewall of the second inner spacer 250d in contact with the second gate line GLd2 may have a shape in which the center of the sidewall protrudes toward the second gate line GLd2. That is, the sidewall of the second inner spacer 250d in contact with the second gate line GLd2 may have a shape protruding outward.

FIGS. 14 to 18 are cross-sectional views for describing, in a process order, a method of fabricating a semiconductor device, according to some example embodiments.

Particularly, FIGS. 14 to 18 are cross-sectional views taken along lines Y1-Y1′ and Y2-Y2′ of FIG. 1 in a process order.

Referring to FIGS. 14 to 18, a method of fabricating the semiconductor device 10 may include forming a mask M in the second area B (see FIG. 1) of the substrate 102, etching a preliminary first active pattern PNS1, forming the semiconductor material layer 140, removing the mask M, forming the first and second gate dielectric layers 152 and 252, and forming the first and second gate lines GL1 and GL2.

FIG. 14 shows an operation of forming the mask M on the second area B (see FIG. 1) of the substrate 102, in which the second active pattern NS2 is above the second fin-type active region FB, while the preliminary first active pattern PNS1 is above the first fin-type active region FA. The preliminary first active pattern PNS1 and the second active pattern NS2 may be respectively formed above the first and second fin-type active regions FA and FB through a process of alternately stacking Si and SiGe and patterning the stacked Si and SiGe. Thereafter, the mask M may be formed on the second fin-type active region FB to protect the second active pattern NS2 from the outside.

In some example embodiments, a thickness T_PNS1 of the preliminary first active pattern PNS1 may be substantially the same or the same as the thickness T_NS2 of the second active pattern NS2. In some example embodiments, the first device isolation layer 114a may be at both sides of the first fin-type active region FA and the second device isolation layer 114b may be at both sides of the second fin-type active region FB. A first thickness PH_a of the first device isolation layer 114a may be substantially the same or the same as the second thickness H_b of the second device isolation layer 114b. That is, in an operation of forming the preliminary first active pattern PNS1 and the second active pattern NS2, there may be no substantial difference between the first area A (see FIG. 1) and the second area B (see FIG. 1).

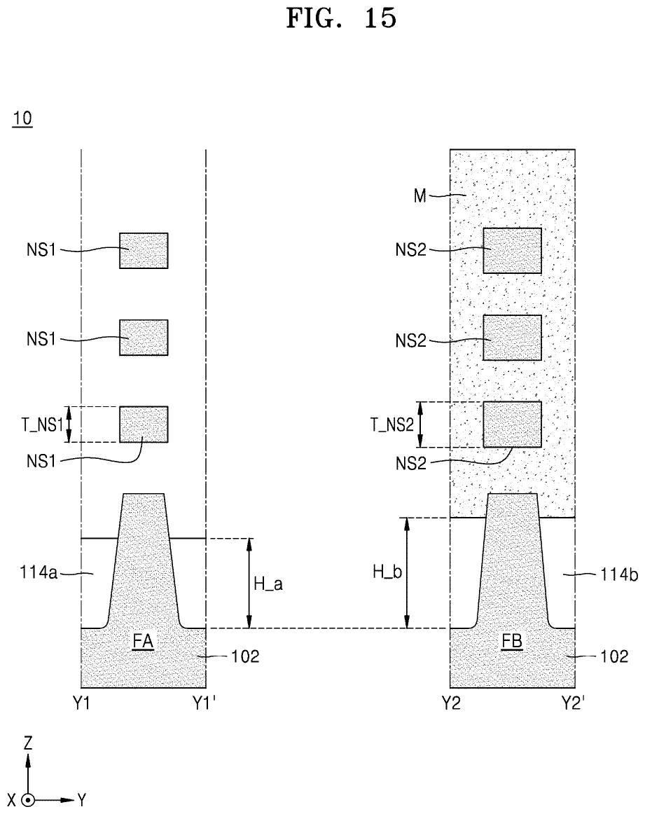

Next, FIG. 15 shows that an etching process on the preliminary first active pattern PNS1 has been performed. The preliminary first active pattern PNS1 is not protected by the mask M, and thus, the thickness of the preliminary first active pattern PNS1 may be reduced by the etching process. Also, the first device isolation layer 114a is not protected by the mask M, and thus, the thickness of the first device isolation layer 114a may be reduced. The second active pattern NS2 in the second area B (see FIG. 1) is protected from the outside, and thus, the size of the second active pattern NS2 is not changed during the etching process.

That is, the preliminary first active pattern PNS1 becomes the first active pattern NS1 having upper and lower surfaces recessed inward, and the thickness of the first active pattern NS1 may be less than the thickness of the second active pattern NS2. The first thickness H_a of the first device isolation layer 114a may be less than the second thickness H_b of the second device isolation layer 114b.

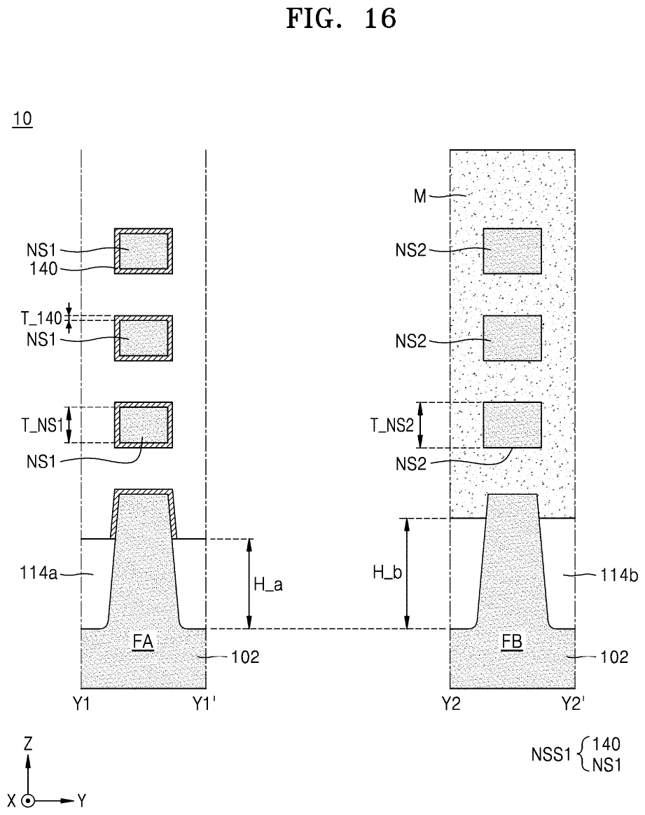

Next, FIG. 16 shows an operation of forming the semiconductor material layer 140 on the surface of the first active pattern NS1. The semiconductor material layer 140 may be formed on the surface of the first active pattern NS1 through epitaxial growth. The semiconductor material layer 140 may be conformally formed on the surface of the first active pattern NS1. In some example embodiments, the semiconductor material layer 140 may be grown by an etched height of the preliminary first active pattern PNS1. That is, a sum of the thickness T_140 of the semiconductor material layer 140 and the thickness T_NS1 of each of the plurality of first active patterns NS1 may be substantially the same or the same as the thickness T_NS2 of each of the plurality of second active patterns NS2.

In some example embodiments, an operation of forming first and second inner spacers may be further included. The first inner spacer may be formed to be in contact with the semiconductor material layer 140 and the second inner spacer may be formed to be in contact with a second source/drain region. However, the operation of forming the first and second inner spacers is not limited thereto and may be performed before forming the preliminary first active pattern PNS1 and the second active pattern NS2.

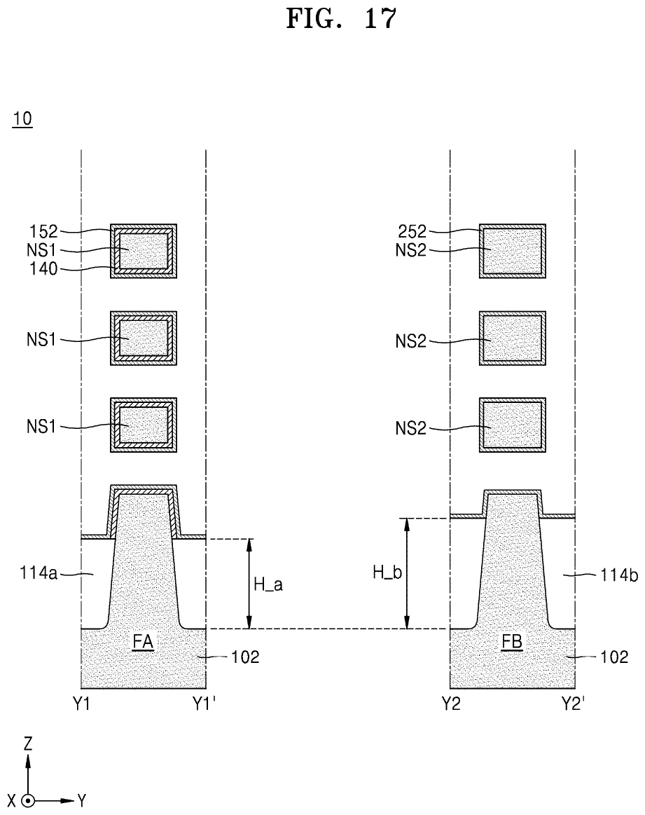

Next, FIG. 17 shows an operation of removing the mask M from the second area B (scc FIG. 1), forming the first gate dielectric layer 152 on the semiconductor material layer 140, and forming the second gate dielectric layer 252 on the second active pattern NS2.

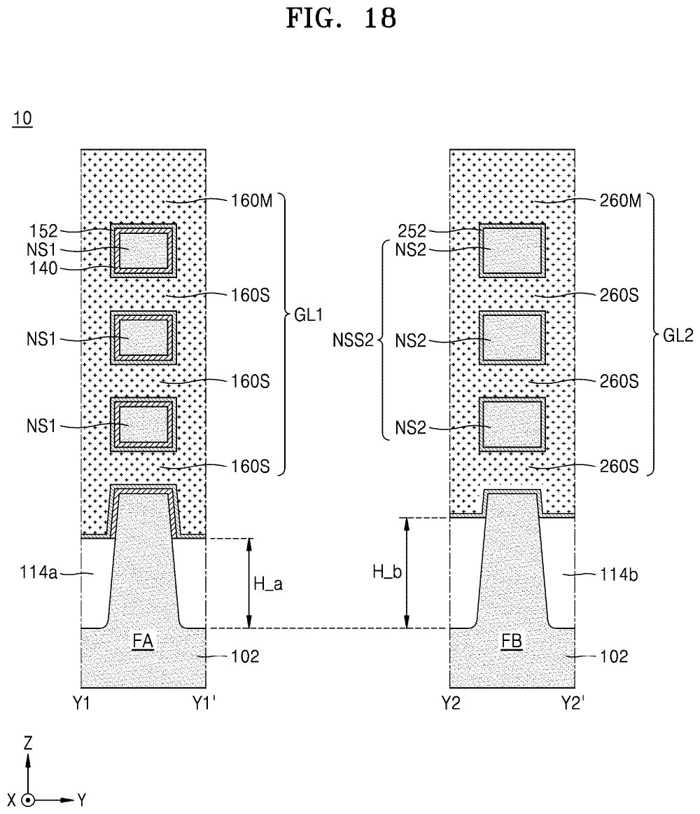

Next, FIG. 18 shows an operation of forming the first gate line GL1 and the second gate line GL2. Herein, a material of the first gate line GL1 may be different from a material of the second gate line GL2.

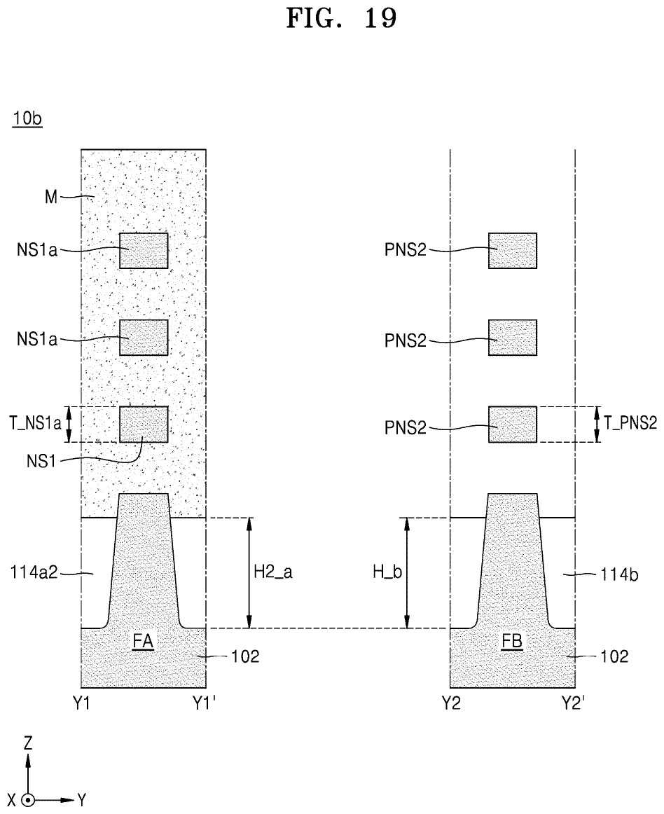

FIGS. 19 to 23 are cross-sectional views for describing, in a process order, a method of fabricating the semiconductor device 10b, according to some example embodiments.

Referring to FIGS. 19 to 23, the method of fabricating the semiconductor device 10b may include forming the mask M on the first area A (see FIG. 1) of the substrate 102, forming a semiconductor material layer on the first active pattern NS1a, removing the mask M from the first area A (see FIG. 1) of the substrate 102 and forming the mask M on the second area B (see FIG. 1) of the substrate 102, growing the thickness of the second active pattern NS2, removing the mask M on the second area B (see FIG. 1), forming the first and second gate dielectric layers 152 and 252, and forming the first and second gate lines GLa1 and GL2.

FIG. 19 shows an operation of forming the mask M on the first area A (see FIG. 1) of the substrate 102 in which the first active pattern NS1a is above the first fin-type active region FA, while a preliminary second active pattern PNS2 is above the second fin-type active region FB. The first active pattern NS1a and the preliminary second active pattern PNS2 may be respectively formed above the first and second fin-type active regions FA and FB through a process of alternately stacking Si and SiGe and patterning the stacked Si and SiGe. Thereafter, the mask M may be formed on the first fin-type active region FA to protect the first active pattern NS1a from the outside.

In some example embodiments, a thickness T_NS1a of the first active pattern NS1a may be substantially the same or the same as a thickness T_PNS2 of the preliminary second active pattern PNS2. In some example embodiments, a first device isolation layer 114a2 may be at both sides of the first fin-type active region FA and the second device isolation layer 114b may be at both sides of the second fin-type active region FB. A first thickness H2_a of the first device isolation layer 114a2 may be substantially the same or the same as the second thickness H_b of the second device isolation layer 114b.

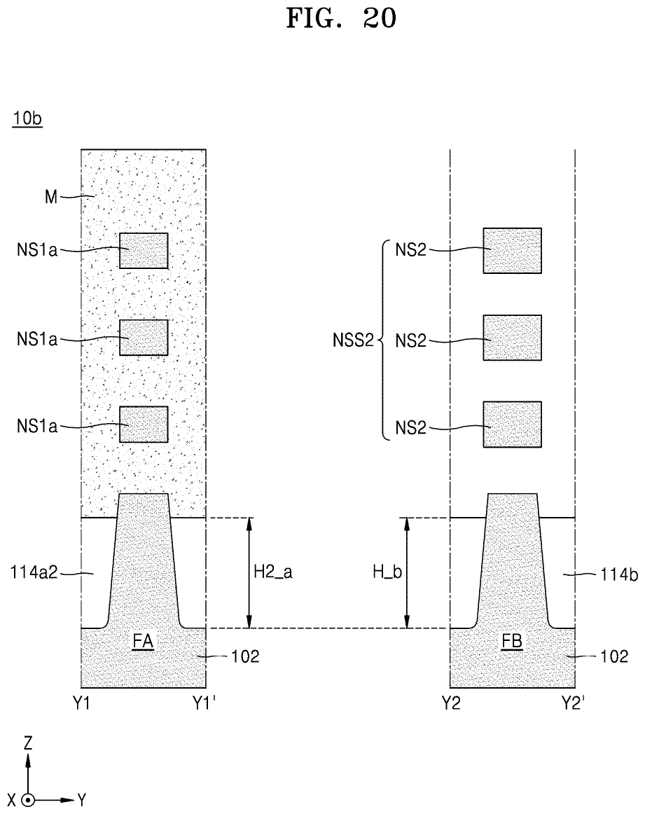

Next, FIG. 20 shows the second active pattern NS2 with an increased thickness from the preliminary second active pattern PNS2 through a deposition process. The first active pattern NS1a is protected from the outside by the mask M, and thus, a deposition process may not be performed on the first active pattern NS1a, thereby resulting in no change in the thickness of the first active pattern NS1a. Accordingly, the thickness T_NS2 of the second active pattern NS2 may be greater than the thickness T_NS1a of the first active pattern NS1a.

In some example embodiments, in the deposition process, because a deposition speed on the second device isolation layer 114b is slower than a deposition speed on the second active pattern NS2, there may be no substantial difference in the second thickness H_b of the second device isolation layer 114b before and after the deposition process.

Next, the mask M on the first area A (see FIG. 1) of the substrate 102 may be removed and the mask M may be formed on the second area B (see FIG. 1) of the substrate 102. That is, the first active pattern NS1a on the first area A (see FIG. 1) of the substrate 102 may be exposed to the outside and the second active pattern NS2 on the second area B (see FIG. 1) of the substrate 102 may be protected by the mask M.

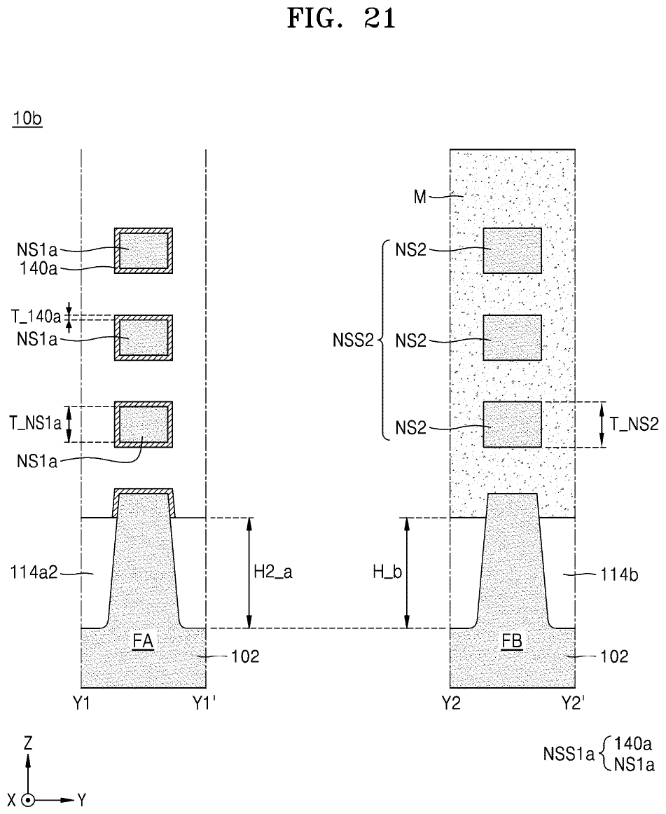

Next, FIG. 21 shows the semiconductor material layer 140a formed on the surface of the first active pattern NS1a. The semiconductor material layer 140a may be formed on the surface of the first active pattern NS1a by growing a material, having a work function that is different from that of the first active pattern NS1a, on the surface of the first active pattern NS1a through a deposition process or epitaxial growth. The upper and lower surfaces of the first active pattern NS1a may be flat.

In some example embodiments, the semiconductor material layer 140a may be conformally formed on the surface of the first active pattern NS1a. In some example embodiments, the semiconductor material layer 140a may be grown by a thickness deposited on the first active pattern NS1a. That is, a sum of a thickness T_140a of the semiconductor material layer 140a and the thickness T_NS1a of each of the plurality of first active patterns NS1a may be substantially the same or the same as the thickness T_NS2 of each of the plurality of second active patterns NS2.

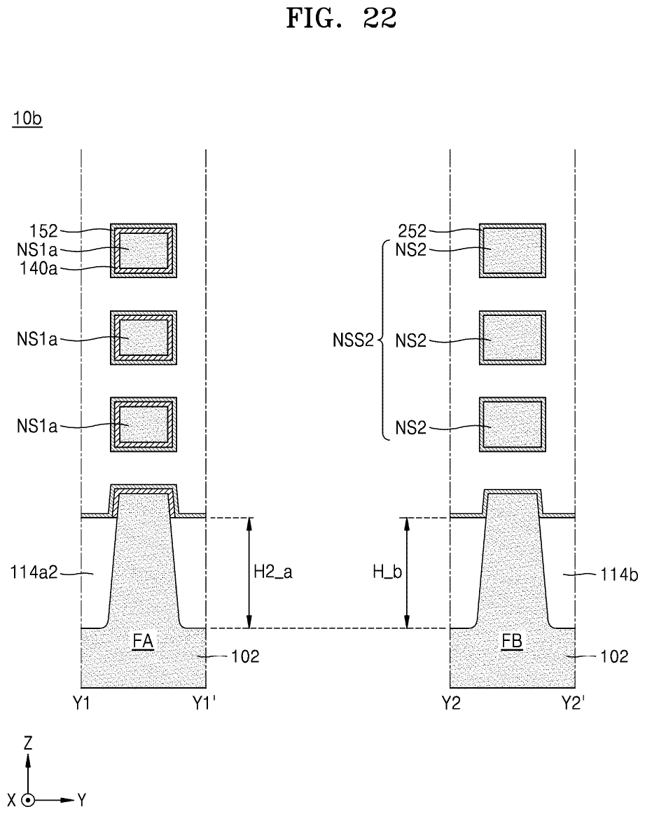

Next, FIG. 22 shows an operation of removing the mask M from the second area B (see FIG. 1), forming the first gate dielectric layer 152 on the semiconductor material layer 140a, and forming the second gate dielectric layer 252 on the second active pattern NS2.

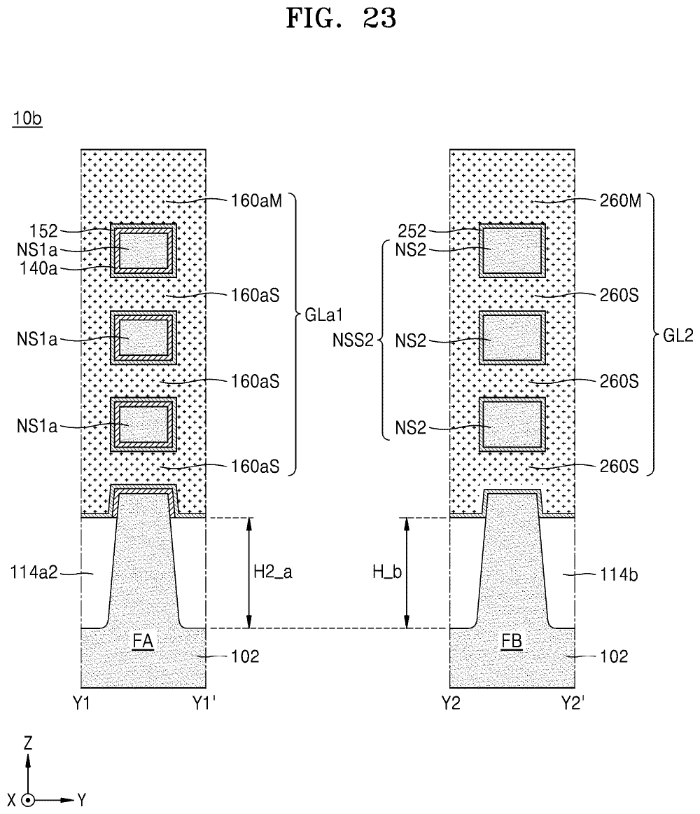

Next, FIG. 23 shows an operation of forming the first gate line GLa1 and the second gate line GL2. Herein, a material of the first gate line GLa1 may be different from a material of the second gate line GL2.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate;
a fin-type active region protruding on the substrate;
a channel region on the fin-type active region and comprising a plurality of active patterns extending in a first horizontal direction and a semiconductor material layer;
a gate line extending in a second horizontal direction, the second horizontal direction being perpendicular to the first horizontal direction, and the gate line covering the channel region on the fin-type active region; and
a pair of source/drain regions at both sides of the gate line on the fin-type active region,
a work function of the semiconductor material layer being different from a work function of the plurality of active patterns,
the semiconductor material layer surrounding portions of the gate line between the plurality of active patterns, and
the gate line being separated from the pair of source/drain regions with the semiconductor material layer therebetween.

2. The semiconductor device of claim 1, further comprising
a pair of inner spacers separated from each other in the first horizontal direction,
wherein a portion of the gate line between two adjacent active patterns is at one side of each of the pair of inner spacers and the semiconductor material layer is at the other side thereof.

3. The semiconductor device of claim 2, wherein both sidewalls of each of the pair of inner spacers have curved surfaces recessed inward.

4. The semiconductor device of claim 2, wherein both sidewalls of the portion of the gate line between two adjacent active patterns are curved surfaces protruding outward.

5. The semiconductor device of claim 2, further comprising a semiconductor cap surrounding the gate line and the pair of inner spacers.

6. The semiconductor device of claim 1, wherein upper and lower surfaces of each of the plurality of active patterns are curved surfaces recessed inward.

7. The semiconductor device of claim 6, wherein, in a region in which the semiconductor material layer is in contact with the plurality of active patterns, the semiconductor material layer is conformally formed along the surfaces of the plurality of active patterns.

8. The semiconductor device of claim 1, wherein each of the plurality of active patterns has flat upper and lower surfaces.

9. The semiconductor device of claim 1, wherein
one side of each of both sidewalls of the semiconductor material layer is in contact with each of the pair of source/drain regions, and
both the sidewalls of the semiconductor material layer have a shape in which centers of both the sidewalls of the semiconductor material layer recess toward the gate line.

10. The semiconductor device of claim 1, wherein a thickness of the semiconductor material layer is 1 nm to 1.5 nm.

11. The semiconductor device of claim 1, wherein
a material constituting the plurality of active patterns includes silicon, and
a material constituting the semiconductor material layer includes silicon germanium.

12. The semiconductor device of claim 11, wherein a germanium concentration of the silicon germanium in the semiconductor material layer is 20% to 60%.

13. A semiconductor device comprising:
a substrate including a first area and a second area;
first and second fin-type active regions protruding on the substrate;
a first channel region on the first fin-type active region and comprising a plurality of first active patterns extending in a first horizontal direction and a semiconductor material layer surrounding at least portions of the plurality of first active patterns;
a first gate line covering the first channel region on the first fin-type active region;
a second channel region on the second fin-type active region and comprising a plurality of second active patterns extending in the first horizontal direction,
a second gate line covering the second channel region on the second fin-type active region;
a pair of first source/drain regions at both sides of the first gate line on the first fin-type active region; and
a pair of second source/drain regions at both sides of the second gate line on the second fin-type active region,
the first fin-type active region being in the first area of the substrate,
the second fin-type active region being in the second area of the substrate, and
in the semiconductor material layer, at least one of a surface in contact with the plurality of first active patterns and a surface in contact with the first gate line being a curved surface.

14. The semiconductor device of claim 13, wherein a thickness of each of the plurality of first active patterns in the first channel region is less than a thickness of each of the plurality of second active patterns in the second channel region.

15. The semiconductor device of claim 13, wherein a sum of a thickness of each of the plurality of first active patterns in the first channel region and a thickness of the semiconductor material layer is same as a thickness of each of the plurality of second active patterns in the second channel region.

16. The semiconductor device of claim 13, further comprising:
a first device isolation layer covering both side surfaces of the first fin-type active region; and
a second device isolation layer covering both side surfaces of the second fin-type active region,
wherein a thickness of the first device isolation layer is less than or equal to a thickness of the second device isolation layer.

17. The semiconductor device of claim 13, further comprising a pair of first inner spacers and a pair of second inner spacers,
wherein
the pair of first inner spacers are at both sides of a portion of the first gate line between two adjacent first active patterns, both the sides of the portion of the first gate line facing each other in the first horizontal direction,
the pair of second inner spacers are at both sides of a portion of the second gate line between two adjacent second active patterns, both the sides of the portion of the second gate line facing each other in the first horizontal direction,
each of the pair of first inner spacers is in contact with an adjacent one of the pair of first source/drain regions, and
each of the pair of second inner spacers is in contact with an adjacent one of the pair of second source/drain regions.

18. The semiconductor device of claim 16, wherein
both sidewalls of a portion of the first gate line between two adjacent first active patterns, both the sidewalls of the portion of the first gate line facing each other in the first horizontal direction, have curved surfaces recessed inward, and
both sidewalls of a portion of the second gate line between two adjacent second active patterns, both the sidewalls of the portion of the second gate line facing each other in the first horizontal direction, have curved surfaces recessed inward.

19. The semiconductor device of claim 16, wherein
both sidewalls of a portion of the first gate line between two adjacent first active patterns, both the sidewalls of the portion of the first gate line facing each other in the first horizontal direction, have curved surfaces protruding outward, and
both sidewalls of a portion of the second gate line between two adjacent second active patterns, both the sidewalls of the portion of the second gate line facing each other in the first horizontal direction, have curved surfaces protruding outward.

20. A semiconductor device comprising:
a substrate including a first area and a second area;
first and second fin-type active regions protruding on the substrate;
a first channel region on the first fin-type active region and comprising a plurality of first active patterns extending in a first horizontal direction and a semiconductor material layer surrounding at least portions of the plurality of first active patterns;
a first gate line covering the first channel region on the first fin-type active region;
a pair of first inner spacers separated from each other in the first horizontal direction with the first gate line therebetween;
a second channel region on the second fin-type active region and comprising a plurality of second active patterns extending in the first horizontal direction;
a second gate line covering the second channel region on the second fin-type active region;
a pair of first source/drain regions at both sides of the first gate line on the first fin-type active region; and
a pair of second source/drain regions at both sides of the second gate line on the second fin-type active region,
the first fin-type active region being in the first area of the substrate,
the second fin-type active region being in the second area of the substrate,
a work function of the semiconductor material layer being different from a work function of the plurality of first active patterns,
the semiconductor material layer surrounding a portion of the first gate line between two adjacent first active patterns and the pair of first inner spacers, and
the first gate line being separated from the pair of first source/drain regions with the semiconductor material layer and the pair of first inner spacers therebetween.
